(19) United States
(12) Patent Application Publication
(10) Pub. No.: US 2010/0117046 A1
(43) Pub. Date: May 13, 2010

(54) PHASE CHANGE MEMORY DEVICE HAVING REDUCED PROGRAMMING CURRENT AND METHOD FOR MANUFACTURING THE SAME

(76) Inventors: Heon Yong CHANG, Gyeonggi-do (KR); Sang Heon KIM, Seoul (KR)

Correspondence Address: LADAS & PARRY LLP, 224 SOUTH MICHIGAN AVENUE, SUITE 1600, CHICAGO, IL, 60604, US

(21) Appl. No.: 12/346,389

(22) Filed: Dec. 30, 2008

(30) Foreign Application Priority Data
Nov. 10, 2008 (KR) 10-2008-0111255

(51) Int. Cl. H01L 47/00; H01L 21/00

(52) U.S. Cl. 257/3; 257/4; 438/102; 257/E47.001; 257/E21.001

(57) ABSTRACT

A phase change memory device includes a semiconductor substrate having an active region. An insulation layer is formed on the semiconductor substrate grooves and holes are defined in the insulation layer, with the holes being defined under the grooves to expose portions of the active region. Cell switching are elements formed in the holes and lower portions of the grooves and a phase change layer formed in upper portions of the grooves over the cell switching elements and on portions of the insulation layer adjacent to the grooves such that the phase change layer has a pore structure. Top electrodes are formed on the phase change layer.

### CROSS-REFERENCE TO RELATED APPLICATIONS

The present application claims priority to Korean patent application number 10-2008-0111255 filed on Nov. 10, 2008, which is incorporated herein by reference in its entirety.

### BACKGROUND OF THE INVENTION

The present invention relates generally to a phase change memory device and a method for manufacturing the same, and more particularly to a phase change memory device in which a phase change layer has a self-aligned contact structure and a pore structure and a method for manufacturing the same.

In general, memory devices are largely divided into a volatile random access memory (RAM), i.e., a memory that cannot maintain information stored therein when power is interrupted, and a non-volatile read-only memory (ROM), i.e., a memory capable of continuously maintaining the stored state of inputted information even when power is interrupted. Examples of the volatile RAM include a dynamic RAM (DRAM) and a static RAM (SRAM). Examples of the non-volatile ROM include a flash memory device such as an electrically erasable and programmable ROM (EEPROM).

The DRAM is generally considered to be an excellent memory device, however, the DRAM requires high charge storing capacity, and as a result of this, in the DRAM memory device it is difficult to accomplish a high level of integration because the surface area of an electrode must be increased. Further, in the flash memory device, two gates are stacked on each other, and therefore a high operation voltage is required when compared to a power supply voltage. As such, in the DRAM memory device it is also difficult to accomplish a high level of integration because a separate booster circuit is needed to generate a voltage necessary for write and delete operations.

In light of aforementioned shortcomings associated with the DRAM memory device, a novel memory device having a simple configuration and being capable of accomplishing a high level of integration while retaining the characteristics of a non-volatile memory device is desirable in the art. As one example of such a memory device, a phase change memory device has been disclosed in the art. The phase change memory device includes a phase change layer interposed between a bottom electrode and a top electrode. The phase change layer is configured to undergo a phase change from a crystalline state to an amorphous state due to current flow between the bottom electrode and the top electrode. According to the phase change information can be stored in a cell of the phase change memory device and the information stored in a cell can recognized by the difference in resistance between the crystalline state and the amorphous state of the phase change layer.

It is critical in developing a phase change memory device to reduce a programming current. In this regard, several phase change memory devices employ vertical PN diodes as cell switching elements in place of NMOS transistors. Typically, the vertical PN diodes employed in the phase change memory device have a high degree of current flow. Further, by employing the vertical PN diodes current flow can be increased and the size of cells can be decreased, and as such a highly integrated phase change memory device may be realized.

In the phase change memory device employing vertical PN diodes as cell switching elements, heaters are formed under a phase change layer so that current flow to the phase change layer occurs through the heaters. The heaters are formed in holes having a size no greater than 100 nm in consideration of the contact area between the heaters and the phase change layer.

However, problems arise in the conventional art, that is, an etch loss occurs on the upper ends of the cell switching elements when defining holes for forming the heaters, and as a result, contact resistance becomes non-uniform.

Also, in the conventional art, since the holes, in which the heaters are to be formed and which have a size no greater than 100 nm, are simultaneously defined through an etching process, as a result, the holes formed through the etching process are non-uniform. Accordingly, in the conventional art, the contact area between the heater and the phase change layer varies from place to place, and therefore programming current distribution increases.

### SUMMARY OF THE INVENTION

Embodiments of the present invention include a phase change memory device capable of preventing etch loss from occurring on the upper ends of cell switching elements and a method for manufacturing the same.

Also, embodiments of the present invention include a phase change memory device capable of preventing non-uniformity of contact resistance and a method for manufacturing the same.

Further, embodiments of the present invention include a phase change memory device which can uniformize the contact area between a heater and a phase change layer and a method for manufacturing the same.

In addition, embodiments of the present invention include a phase change memory device which can decrease programming current distribution and a method for manufacturing the same.

In one aspect of the present invention, a phase change memory device comprises an insulation layer formed on a semiconductor substrate and having grooves and holes which are defined under the grooves; cell switching elements formed in the holes and the grooves to be recessed; a phase change layer formed on the recessed cell switching elements and on adjacent portions of the insulation layer to have a pore structure; and top electrodes formed on the phase change layer.

The phase change memory device further comprises spacers formed on sidewalls of the grooves to have a thickness that allows the spacers to overlap with the holes.

The cell switching elements comprise vertical PN diodes.

The cell switching elements are formed such that they are recessed from an upper surface of the insulation layer by a distance in the range of 200˜1,000 Å.

The phase change memory device further comprises a metal-silicide layer interposed between the cell switching elements and the phase change layer.

In another aspect of the present invention, a phase change memory device comprises a semiconductor substrate having an active region; an insulation layer formed on the semiconductor substrate and having grooves and holes which are defined under the grooves and expose portions of the active region; cell switching elements formed in lower portions of the grooves and in the holes; a phase change layer formed in upper portions of the grooves over the cell switching elements and on adjacent portions of the insulation layer to have a pore structure; and top electrodes formed on the phase change layer.

The active region is a bar type.

The phase change memory device further comprises an N+ base area formed in a surface of the active region.

The N+ base area has an impurity concentration in the range of 1×10²⁰˜1×10²² ions/cm³.

The grooves have a greater diameter than the holes.

The grooves have a depth in the range of 200˜1,000 Å.

The phase change memory device further comprises spacers formed on sidewalls of the grooves to have a thickness that no allows the spacers to overlap with the holes.

The spacers comprise at least one of a nitride layer and an oxide layer.

The groove has a diameter in the range of 200˜1000 Å when measured between facing surfaces of lower ends of the spacers.

The holes have a diameter in the range of 500˜1500 Å.

The cell switching elements are formed such that they are recessed from an upper surface of the insulation layer by a distance in the range of 200˜1,000 Å.

The cell switching elements comprise vertical PN diodes having a structure in which an N-type silicon layer and a P-type silicon layer are stacked.

The N-type silicon layer has an impurity concentration of in the range 1×10¹⁸˜1×10²⁰ ions/cm³.

The P-type silicon layer has an impurity concentration in the range of 1×10²⁰˜1×10²² ions/cm³.

The phase change memory device further comprises a metal-silicide layer interposed between the cell switching elements and the phase change layer.

The metal-silicide layer comprises any one of a titanium (Ti) silicide layer, a niobium (Nb) silicide layer, and a cobalt (Co) silicide layer.

The phase change layer is formed of a compound which contains at least one of Ge, Sb and Te.

The phase change layer is ion-implanted with at least one of oxygen, nitrogen and silicon.

The top electrodes are formed of any one among TiAlN, TiW, TiN and WN.

The phase change layer and the top electrodes are a line type.

In still another aspect of the present invention, a method for manufacturing a phase change memory device comprises the steps of forming an insulation layer on a semiconductor substrate which has grooves and holes defined under the grooves; forming cell switching elements in lower portions of the grooves and in the holes; forming a phase change material layer in upper portions of the grooves over the cell switching elements and on the insulation layer; forming a conductive layer for top electrodes on the phase change material layer; and etching the conductive layer for top electrodes and the phase change material layer, and thereby forming a phase change layer having a pore structure and top electrodes in the upper portions of the grooves and on adjacent portions of the insulation layer.

The method further comprises the step of forming spacers on sidewalls of the grooves to a thickness that allows the spacers to overlap with the holes.

The cell switching elements comprise vertical PN diodes.

The cell switching elements are formed such that they are recessed from an upper surface of the insulation layer by a distance in the range of 200˜1,000 Å.

The method further comprises the step of forming a metal-silicide layer between the cell switching elements and the phase change layer.

In a still further aspect of the present invention, a method for manufacturing a phase change memory device comprises the steps of forming an insulation layer on a semiconductor substrate having an active region; defining grooves by etching a partial thickness of the insulation layer; forming spacers on sidewalls of the grooves; defining holes by etching portions of the insulation layer which constitute bottoms of the grooves, to expose portions of the active region; forming cell switching elements in lower portions of the grooves and in the holes; forming a phase change material layer in upper portions of the grooves and on the insulation layer; forming a conductive layer for top electrodes on the phase change material layer; and etching the conductive layer for top electrodes and the phase change material layer and thereby forming a phase change layer having a pore structure and top electrodes.

The active region is formed in a bar type.

Before the step of forming the insulation layer, the method further comprises the step of forming an N+ base area in a surface of the active region.

The N+ base area is formed to have an impurity concentration in the range of 1×10²⁰˜1×10²² ions/cm³.

The N+ base area is formed by implanting P or As ions with energy in the range of 10˜100 keV.

The grooves are defined to have a depth in the range of 200˜1,000 Å.

The spacers comprise at least one of a nitride layer and an oxide layer.

The spacers are formed to overlap with the holes.

The spacers are formed such that the grooves have a diameter in the range of 200˜1000 Å when measured between facing surfaces of lower ends of the spacers.

The step of defining the holes by etching the portions of the insulation layer which constitute the bottoms of the grooves is implemented through a wet etching process.

The holes are defined to have a diameter of 500˜1500 Å.

The cell switching elements formed in the lower portions of the grooves and in the holes comprise vertical PN diodes.

The vertical PN diodes are formed through the steps of forming an N-type silicon layer to fill the grooves and the holes; recessing the N-type silicon layer; and converting an upper portion of the recessed N-type silicon layer into a P-type silicon layer.

The step of forming the N-type silicon layer is implemented through a selective epitaxial growth process.

The N-type silicon layer is formed to have an impurity concentration in the range of 1×10¹⁸˜1×10²⁰ ions/cm³.

The step of recessing the N-type silicon layer is implemented such that the N-type silicon layer is recessed from an upper surface of the insulation layer by a distance of 200˜1,000 Å.

The P-type silicon layer is formed to have an impurity concentration in the range of 1×10²⁰1×10²² ions/cm³.

The P-type silicon layer is formed by implanting B or BF₂ ions with energy in the range of 10˜100 keV.

The vertical PN diodes are formed through the steps of forming a silicon layer to fill the grooves and the holes; recessing the silicon layer; forming an N-type silicon layer in a lower portion of the recessed silicon layer; and forming a P-type silicon layer in an upper portion of the recessed silicon layer.

The step of forming the silicon layer is implemented through a selective epitaxial growth process.

The step of recessing the silicon layer is implemented such that the silicon layer is recessed from an upper surface of the insulation layer by a distance in the range of 200˜1,000 Å.

The N-type silicon layer is formed to have an impurity concentration in the range of 1×10¹⁸˜1×10²⁰ ions/cm³.

The N-type silicon layer is formed by implanting P or As ions with energy in the range of 10˜100 keV.

The P-type silicon layer is formed by implanting B or BF₂ ions with energy in the range of 10˜100 keV.

The P-type silicon layer is formed by implanting B or BF₂ ions with energy in the range of 10˜100 keV.

After the step of forming the cell switching elements and before the step of forming the phase change material layer, the method further comprises the step of forming a metal-silicide layer on the cell switching elements.

The metal-silicide layer comprises any one of a titanium (Ti) silicide layer, a niobium (Nb) silicide layer, and a cobalt (Co) silicide layer.

The phase change layer is formed of a compound which contains at least one of Ge, Sb and Te.

The phase change layer is ion-implanted with at least one of oxygen, nitrogen and silicon.

The top electrodes are formed of any one among TiAlN, TiW, TiN and WN.

The phase change layer and the top electrodes are formed in a line type.

### BRIEF DESCRIPTION OF THE DRAWINGS

FIG. 1 is a cross-sectional view showing a phase change memory device in accordance with an embodiment of the present invention.

FIGS. 2A through 2H are cross-sectional views shown for illustrating the processes of a method for manufacturing a phase change memory device in accordance with another embodiment of the present invention.

FIG. 3 is a cross-sectional view showing a phase change memory device in accordance with still another embodiment of the present invention.

### DESCRIPTION OF SPECIFIC EMBODIMENTS

Hereafter, specific embodiments of the present invention will be described in detail with reference to the accompanying drawings.

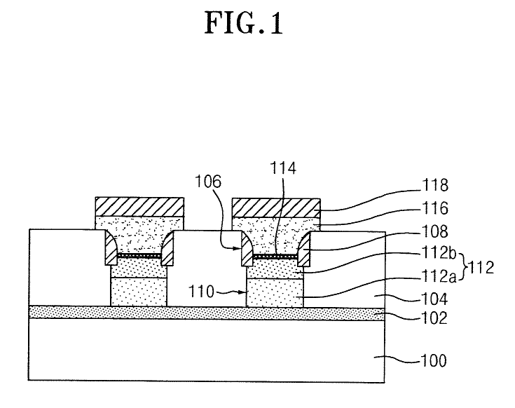

FIG. 1 is a cross-sectional view showing a phase change memory device in accordance with an embodiment of the present invention.

Referring to FIG. 1, a semiconductor substrate 100 having an active region is prepared. The active region is formed to have the shape of a bar. An N+ base area 102 is formed in the surface of the active region of the semiconductor substrate 100. According to an embodiment of the present invention, the N+ base area 102 has an impurity concentration in the range of 1×10²⁰˜1×10²² ions/cm³. The N+ base area 102 serves as an electrode which electrically connects cell switching elements and a word line.

An insulation layer 104 is formed on the semiconductor substrate 100 including the N+ base area 102. Grooves 106 and holes 110 are defined in the insulation layer 104. As shown in FIG. 1, according to an embodiment of the present invention, the holes 110 are positioned under the grooves 106 so as to expose portions of the active region formed with the N+ base area 102. The holes 110 have a diameter, for example, in the range of 500˜1500 Å. According to the present embodiment the grooves 106 have a diameter greater than that of the holes 110. Moreover, the grooves 106 have a depth, for example, in the range of 200˜1,000 Å.

Spacers 108 are formed on the sidewalls of the grooves 106. The spacers 108 are formed to a predetermined thickness such that the spacers 108 overlap with the hole 110. That is, the spacers 108 are formed to a thickness that allows a partial thickness of the spacer 108 to project from the sidewall of the hole 110. The spacers 108 are formed as at least one of a nitride layer and an oxide layer. The grooves 106 have a diameter in the range of 200˜1000 Å when measured between the facing surfaces of the lower ends of the spacers 108.

Vertical PN diodes 112 serving as cell switching elements are formed in the holes 110 and a lower portion of the grooves 106. The vertical PN diodes 112 have a structure in which an N-type silicon layer 112a and a P-type silicon layer 112b are stacked. The N-type silicon layer 112a has an impurity concentration in the range of 1×10¹⁸˜1×10²⁰ ions/cm³₁ and the P-type silicon layer 112b has an impurity concentration in the range of 1×10²⁰˜1×10²² ions/cm³. The vertical PN diodes 112 are formed such that they are recessed from the upper surface of the insulation layer 104, for example, by 200˜1,000 Å.

A metal-silicide layer 114 is formed on the surfaces of the vertical PN diodes 112 to form ohmic contacts with a phase change layer 116. The metal-silicide layer 114 comprises at least one of a titanium (Ti) silicide layer, a niobium (Nb) silicide layer, and a cobalt (Co) silicide layer.

As shown in FIG. 1, the phase change layer 116 is formed in upper portions of the grooves 106 and on the adjacent portions of the insulation layer 104. The phase change layer 116 has a self-aligned contact structure and contacts the vertical PN diodes 112 serving as cell switching elements. Also, since the phase change layer 116 is filled in the upper portions of the grooves 106, it has a pore structure. The phase change layer 116 is formed of a compound that contains at least one of germanium Ge, stibium Sb, and tellurium Te and is ion-implanted with at least one of oxygen, nitrogen, and silicon. Top electrodes 118 are formed on the phase change layer 116. The top electrodes 118 are formed of at least one of TiAlN, TiW, TiN, and WN. The stack patterns of the phase change layer 116 and the top electrodes 118 are preferably formed to have a line shape.

In the phase change memory device according to an embodiment of the present invention, configured as described above, a phase change layer has a pore structure because the phase change layer is formed within grooves, and, additionally, the phase change layer has a self-aligned contact structure with respect to vertical PN diodes serving as cell switching elements.

Accordingly, according to an embodiment of the present invention, the etch loss of the vertical PN diodes as cell switching elements does not occur. Therefore, in a phase change memory device according to an embodiment the present invention, uniform contact resistance is obtained between the vertical PN diodes and the phase change layer. Furthermore, in a phase change memory device according to the present invention, the contact area between the cell switching element and the phase change layer is uniform, and therefore, a programming current distribution can be decreased when compared to the conventional art. In addition, in the phase change memory device according to the present invention, due to the fact that the phase change layer has the pore structure, the programming current can be reduced, and a difference in Joule's heat between cells can be decreased, whereby the operation characteristics of the phase change memory device can be improved.

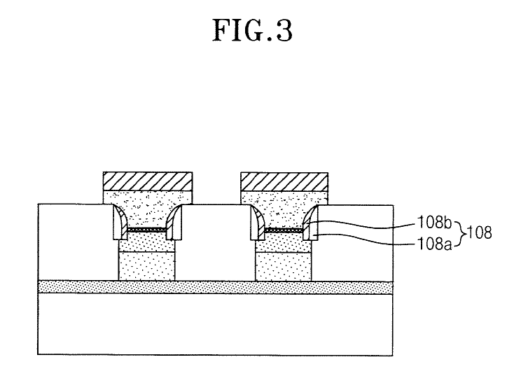

While it was described in the above embodiment that the spacers comprise a single layer of an oxide layer or a nitride layer, it should be understood that according to another embodiment of the present invention the spacers 108 may comprise a stack structure, for example, of an oxide layer and a nitride layer as shown in FIG. 3.

As shown in FIG. 3, a first spacer 108a comprises any one of an oxide layer or an oxynitride layer, and a second spacer 108b is formed of a material different from that of the first spacer 108a. For example, the second spacer 108b may comprise a nitride layer or an oxide layer.

In the phase change memory device according to another embodiment of the present invention, the contact area between vertical PN diodes, which serve as cell switching elements, and a phase change layer is further decreased, and therefore, a programming current is further reduced accordingly.

The structure of the phase change memory device according to the present embodiment is similar to that described above, and as such the detailed description of same elements will be omitted herein.

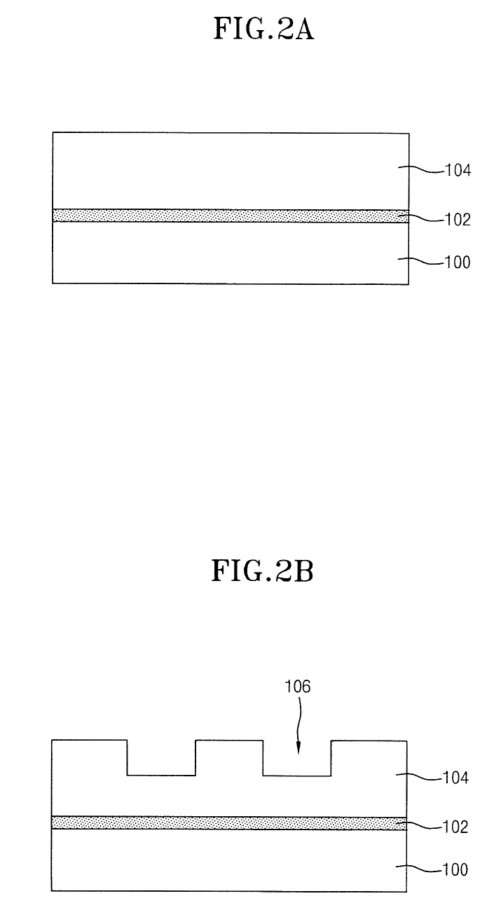

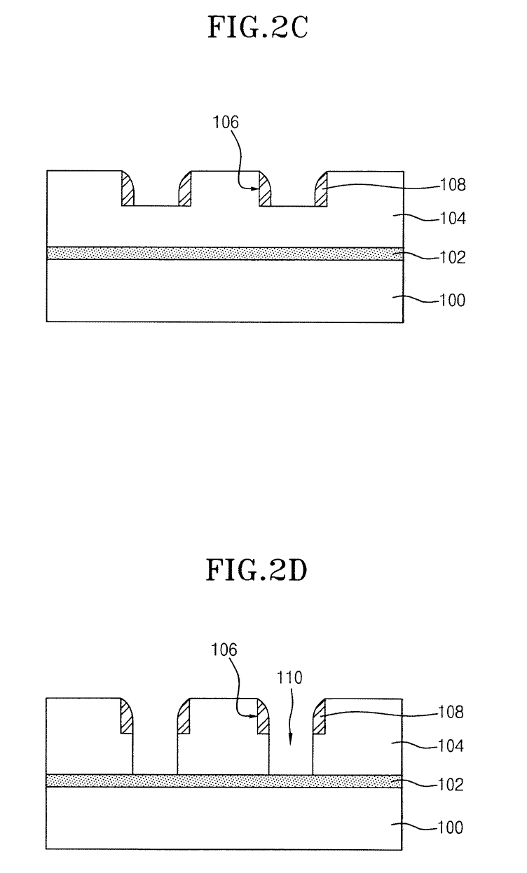

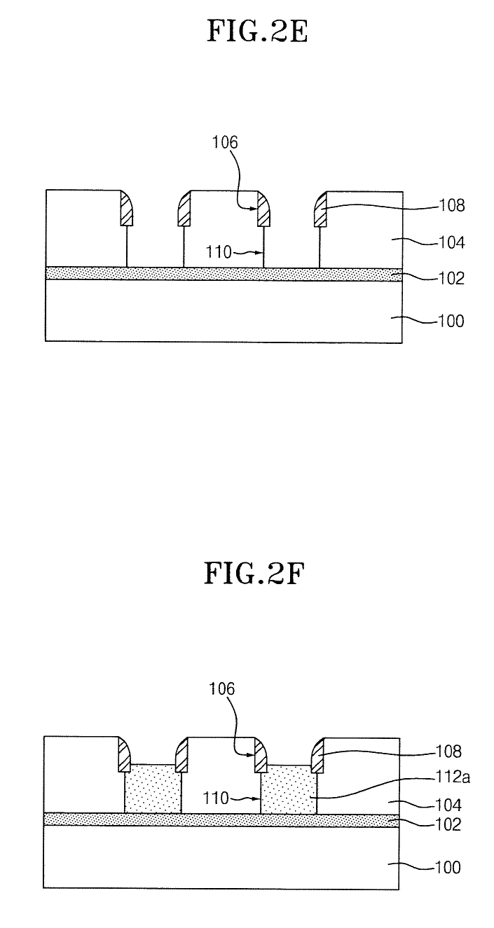

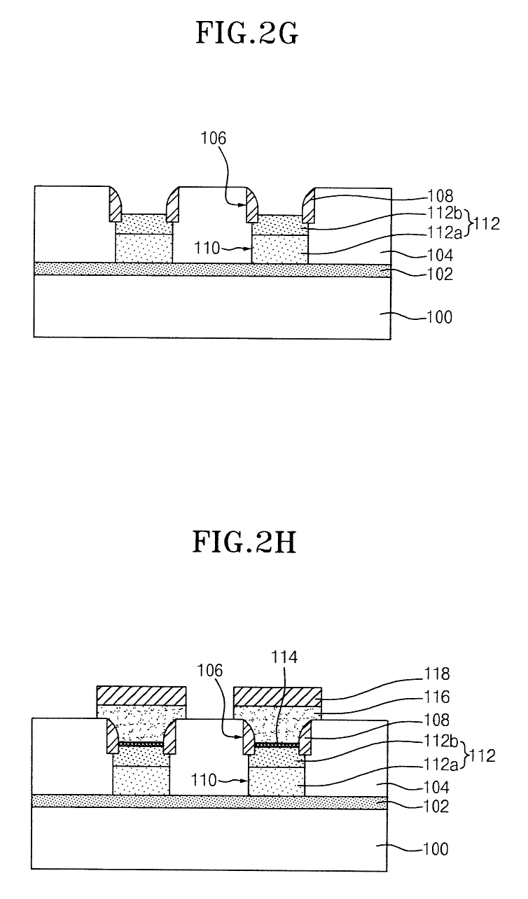

FIGS. 2A through 2H are cross-sectional views shown for illustrating the processes of a method for manufacturing a phase change memory device in accordance with an embodiment of the present invention which will be described hereinbelow.

Referring to FIG. 2A, a semiconductor substrate 100 having active region formed in the shape of a bar is prepared. An N+ base area 102 is formed by implanting P or As ions into the active region of the semiconductor substrate 100 with an energy in the range of 10˜100 keV so as to have an impurity concentration in the range of 1×10²⁰˜1×10²² ions/cm³. An insulation layer 104 is formed on the semiconductor substrate 100 including the N+ base area 102.

Although not shown in the drawings, according to an embodiment of the present invention, a nitride layer may be formed on the insulation layer 104 to protect underlying layers in a subsequent etching process.

Referring to FIG. 2B, grooves 106 are defined in the insulation layer 104 by etching portions of the insulation layer 104 over the N+ base area 102. The grooves 106 are defined to have a depth, for example, in the range of 200˜1,000 Å.

Referring to FIG. 2C, spacers 108 are formed on the sidewalls that define the grooves 106. It is preferable that the spacers 108 comprise a nitride layer. Alternatively, the spacers 108 may comprise an oxide layer instead of the nitride layer. Further, as shown in FIG. 3, the spacers 108 may comprise a stacked layer structure of an oxide layer and a nitride layer in place of a single layer. The spacers 108 allow a subsequently formed phase change layer to both form a self-aligned contact structure and to come into contact with the center portions of cell switching elements so that the phase change memory device according to the present invention may have stable and reliable phase change characteristics. The spacers 108 are formed such that the grooves 106 have a diameter in the range of 200˜1000 Å when measured between facing surfaces of the lower ends of the spacers 108.

Referring to FIG. 2D, a mask pattern (not shown) is formed to cover the upper surface of the insulation layer 104, subsequently the portions of the insulation layer 104 that constitute the bottoms of the grooves 106 are etched using the mask pattern and the spacers 108 as an etch mask, so as to define holes 110 that expose portions of the N+ base area 102. The holes 110 are defined to have a diameter in the range of 200˜1000 Å.

Referring to FIG. 2E, a wet etching process is conducted such that portions of the sidewalls of the insulation layer 104 that define the holes 110 etched sideward, and through this, the diameter of the holes 110 is increased. For example, the wet etching process is conducted such that the holes 110 have a diameter in the range of 500˜1500 Å. As a result of the wet etching process, the holes 110 have a sectional shape which overlaps with the spacers 108. In other words, the spacers 108 have a shape in which a partial thickness of the spacer 108 projects from the sidewall of the holes 110.

Referring to FIG. 2F, an N-type silicon layer 112a is grown from the portions of the N+ base area 102 exposed through the grooves 106 and the holes 110. According to the present embodiment the N-type silicon layer 112a is grown through a selective epitaxial growth process. Subsequently, the N-type silicon layer 112a is etched to be recessed by a distance in the range of 200˜1,000 Å from the upper surface of the insulation layer 104. The N-type silicon layer 112a is formed to have an impurity concentration in the range of 1×10¹⁸˜1×10²⁰ ions/cm³, which is less than that of the N+ base area 102.

Referring to FIG. 2G, an ion-implanting is conducted to ion-implant P-type impurities into the upper portion of the N-type silicon layer 112a so as to convert the upper portion of the N-type silicon layer 112a into a P-type silicon layer 112b. Through this, vertical PN diodes 112 serving as the cell switching elements are formed in the lower portions of the grooves 106 and in the holes 110 such that the vertical PN diodes 112 have a stack structure of the N-type silicon layer 112a and the P-type silicon layer 112b. The P-type silicon layer 112b is formed, for example, by implanting B or BF₂ ions with energy in the range of 10˜100 keV so as to have an impurity concentration in the range of 1×10²⁰˜1×10²²

ions/cm³.

According to an embodiment of the present invention, the vertical PN diodes 112 are formed by ion-implanting P-type impurities after forming the N-type silicon layer 112a. However, alternatively, in another embodiment of the present invention, vertical PN diodes may be formed in a manner such that a silicon layer not doped with impurities is formed, an N-type silicon layer is formed by ion-implanting N-type impurities into the lower portion of the silicon layer, and then, a P-type silicon layer is formed by ion-implanting P-type impurities into the upper portion of the silicon layer. In this case, the N-type silicon layer is formed by implanting P or As ions with an energy in the range of 10˜100 keV so as to have an impurity concentration in the range of 1×10¹⁸˜1×10²⁰ ions/cm³, and the P-type silicon layer is formed by implanting B or BF₂ ions with an energy in the range of 10˜100 keV so as to have an impurity concentration in the range of 1×10²⁰˜1×10²² ions/cm³.

Referring to FIG. 2H, a metal-silicide layer 114 is formed on the P-type silicon layer 112b of the vertical PN diodes 112 according to a process well known in the art. The metal-silicide layer 114 is formed as any one of a titanium (Ti) silicide layer, a niobium (Nb) silicide layer, and a cobalt (Co) silicide layer. The metal-silicide layer 114 is formed to produce ohmic contacts between the vertical PN diodes 112, serving as the cell switching elements, and a phase change layer 116, to be subsequently formed.

A phase change material layer (not shown) is formed in the upper portions of the grooves 106 and on the insulation layer 104, and subsequently a conductive layer (not shown) for top electrodes is formed on the phase change material layer. Next, stack patterns of a phase change layer 116 and top electrodes 118 are formed to have the shape of lines which extend in a direction perpendicular to the N+ base area 102 by etching the conductive layer for top electrodes and the phase change material layer. The phase change layer 116 is formed of a compound which contains any one of Ge, Sb, and Te, and may be ion-implanted with at least one of oxygen, nitrogen, and silicon as the occasion demands. The top electrodes 118 are formed of any one among TiAlN, TiW, TiN, and WN.

The phase change layer 116 is formed in the upper portions of the grooves 106 and on the adjacent portions of the insulation layer 104 so as to have a pore structure. Therefore, according to the present invention, etch loss may be prevented from occurring on the upper ends of the vertical PN diodes 112 because it is not necessary to conduct an etching process for exposing the vertical PN diodes 112, and therefore, according to the present invention, uniform contact resistance is obtained between the vertical PN diodes 112 and the phase change layer 116.

Further, in the present invention, the contact area between the vertical PN diodes 112 and the phase change layer 116 may be decreased through the formation of the spacers 108, whereby a programming current is decreased.

In addition, in the present invention, due to the fact that the phase change layer 116 is filled in the grooves 106, the phase change layer 116 may have a self-aligned contact structure with respect to the vertical PN diodes 112. Accordingly, in the present invention, because uniform contact is obtained between the vertical PN diodes 112 and the phase change layer 116, programming current distribution is decreased when compared to the conventional art, and a difference in Joule's heat between cells can be decreased, whereby the operation characteristics of the phase change memory device are improved.

Thereafter, while not shown in the drawings, by sequentially conducting a series of subsequent processes including processes for forming bit lines and word lines, the manufacture of a phase change memory device according to the embodiment is substantially completed.

Although specific embodiments of the present invention have been described for illustrative purposes, those skilled in the art will appreciate that various modifications, additions, and substitutions are possible, without departing from the scope and the spirit of the invention as disclosed in the accompanying claims.

What is claimed is:

1. A phase change memory device comprising:
a semiconductor substrate having an active region defined therein;
an insulation layer formed on the semiconductor substrate,
wherein grooves and holes are defined in the insulation layer, the holes being defined under the grooves so as expose portions of the active region;
cell switching elements formed in the holes and in lower portions of the grooves;
a phase change layer formed in upper portions of the grooves on the cell switching elements and on portions of the insulation layer adjacent to the grooves such that the phase change layer has a pore structure; and
top electrodes formed on the phase change layer.

2. The phase change memory device according to claim 1, wherein the active region is formed to have a bar shape.

3. The phase change memory device according to claim 1, further comprising:
an N+ base area defined in a surface of the active region.

4. The phase change memory device according to claim 3, wherein the N+ base area has an impurity concentration in the range of 1×10²⁰˜1×10²² ions/cm³.

5. The phase change memory device according to claim 1, wherein the diameter of a groove of the grooves is greater than that of a hole of the holes.

6. The phase change memory device according to claim 1, wherein the grooves are defined in the insulation layer to a depth in the range of 200˜1,000 Å.

7. The phase change memory device according to claim 1, further comprising:
spacers formed on sidewalls of a groove of the grooves, wherein the spacers are formed to have a predetermined thickness such that the spacers overlap a hole of the holes corresponding to the groove.

8. The phase change memory device according to claim 7, wherein the spacers comprise at least one of a nitride layer and an oxide layer.

9. The phase change memory device according to claim 7, wherein a distance between facing surfaces of lower ends of the spacers is a diameter of the groove, the diameter of the groove being in the range of 200˜1000 Å.

10. The phase change memory device according to claim 1, wherein the holes have a diameter in the range of 500˜1500 Å.

11. The phase change memory device according to claim 1, wherein the cell switching elements are formed such that they are recessed from an upper surface of the insulation layer by a distance in the range of 200˜1,000 Å.

12. The phase change memory device according to claim 1, wherein the cell switching elements comprise vertical PN diodes having a structure in which an N-type silicon layer and a P-type silicon layer are stacked.

13. The phase change memory device according to claim 12, wherein the N-type silicon layer has an impurity concentration in the range of 1×10¹⁸˜1×10²⁰ ions/cm³.

14. The phase change memory device according to claim 12, wherein the P-type silicon layer has an impurity concentration in the range of 1×10²⁰˜1×10²² ions/cm³.

15. The phase change memory device according to claim 1, further comprising:
a metal-silicide layer interposed between the cell switching elements and the phase change layer.

16. The phase change memory device according to claim 15, wherein the metal-silicide layer comprises any one of a titanium silicide layer, a niobium silicide layer, and a cobalt silicide layer.

17. The phase change memory device according to claim 1, wherein the phase change layer is formed of a compound comprising at least one of germanium, stibium, and tellurium.

18. The phase change memory device according to claim 17, wherein the phase change layer is ion-implanted with at least one of oxygen, nitrogen, and silicon.

19. The phase change memory device according to claim 1, wherein the top electrodes are formed of at least one of TiAlN, TiW, TiN, and WN.

20. The phase change memory device according to claim 1, wherein the phase change layer and the top electrodes are formed in a line shape.

21. A method for manufacturing a phase change memory device, comprising:
forming an insulation layer on a semiconductor substrate, the insulation having grooves defined therein and holes defined therein under the grooves;
forming cell switching elements in the holes and in lower portions of the grooves;
forming a phase change material layer in upper portions of the grooves over the cell switching elements and on the insulation layer;
forming a conductive layer for top electrodes on the phase change material layer; and
etching both the conductive layer for top electrodes and the phase change material layer so as to form top electrodes and a phase change layer having a pore structure in the upper portions of the grooves and on portions of the insulation layer adjacent to the grooves.

22. The method according to claim 21, further comprising:
forming spacers on sidewalls of a grooves of the grooves, wherein the spacers are formed to a predetermined thickness such that the spacers overlap a hole of the holes corresponding to the groove.

23. The method according to claim 21, wherein the cell switching elements comprise vertical PN diodes.

24. The method according to claim 21, wherein the cell switching elements are formed such that they are recessed from an upper surface of the insulation layer by a distance in the range of 200˜1,000 Å.

25. The method according to claim 21, further comprising:
forming a metal-silicide layer between the cell switching elements and the phase change layer.

26. A method for manufacturing a phase change memory device, comprising:
forming an insulation layer on a semiconductor substrate having an active region defined therein;
defining grooves in the insulation layer by etching a partial thickness of the insulation layer;
forming spacers on sidewalls of the grooves;
defining holes in the insulation layer by etching portions of the insulation layer located at bottoms of the grooves, so as to expose portions of the active region;
forming cell switching elements in the holes and in lower portions of the grooves;
forming a phase change material layer in upper portions of the grooves and on the insulation layer;
forming a conductive layer for top electrodes on the phase change material layer; and
etching both the conductive layer for top electrodes and the phase change material layer and so as to form top electrodes and a phase change layer having a pore structure

27. The method according to claim 26, wherein the active region is formed to have a bar shape.

28. The method according to claim 26, wherein the method further comprises:
before the step of forming the insulation layer, forming an N+ base area in a surface of the active region.

29. The method according to claim 28, wherein the N+ base area is formed to have an impurity concentration in the range of 1×10²⁰˜1×10²² ions/cm³.

30. The method according to claim 28, wherein the N+ base area is formed by implanting P or As ions with an energy in the range of 10˜100 keV.

31. The method according to claim 26, wherein the grooves are defined in the insulation layer to a depth in the range of 200˜1,000 Å.

32. The method according to claim 26, wherein the spacers comprise at least one of a nitride layer and an oxide layer.

33. The method according to claim 26, wherein the spacers are formed to overlap the holes.

34. The method according to claim 26, wherein a distance Is between facing surfaces of lower ends of the spacers is a diameter of the groove, the diameter of the groove being in the range of 200˜1000 Å.

35. The method according to claim 26, wherein defining the holes in the insulation layer by etching the portions of the insulation layer located at the bottoms of the grooves is implemented through a wet etching process.

36. The method according to claim 26, wherein the holes are defined to have a diameter in the range of 500˜1500 Å.

37. The method according to claim 26, wherein the cell switching elements formed in the holes and in the lower portions of the grooves comprise vertical PN diodes.

38. The method according to claim 37, wherein forming the vertical PN diodes comprises:
forming an N-type silicon layer to fill the holes and the grooves;
removing a portion of the N-type silicon layer such that a remaining portion of the N-type silicon layer fills the holes and partially fills the grooves; and
converting an upper portion of the remaining portion of the N-type silicon layer into a P-type silicon layer.

39. The method according to claim 38, wherein forming the N-type silicon layer is implemented through a selective epitaxial growth process.

40. The method according to claim 38, wherein the N-type silicon layer is formed to have an impurity concentration in the range of 1×10¹⁸˜1×10²⁰ ions/cm³.

41. The method according to claim 38, removing a portion of the N-type silicon layer is implemented such that the N-type silicon layer is recessed from an upper surface of the insulation layer by a distance in the range of 200˜1,000 Å.

42. The method according to claim 38, wherein the P-type silicon layer is formed to have an impurity concentration in the range of 1×10²⁰˜1×10²² ions/cm³.

43. The method according to claim 38, wherein the P-type silicon layer is formed by implanting B or BF₂ ions with an energy in the range of 10˜100 keV.

44. The method according to claim 37, wherein forming the vertical PN diodes comprises:
forming a silicon layer to fill the holes and the grooves;
removing a portion of the silicon layer such that a remaining portion of the silicon layer fills the holes and partially fills the grooves;
forming an N-type silicon layer in a lower portion of the remaining portion of the silicon layer; and
forming a P-type silicon layer in an upper portion of the remaining portion of the recessed silicon layer.

45. The method according to claim 44, wherein forming the silicon layer is implemented through a selective epitaxial growth process.

46. The method according to claim 44, wherein removing a portion of the silicon layer is implemented such that the silicon layer is recessed from an upper surface of the insulation layer by a distance in the range of 200˜1,000 Å.

47. The method according to claim 44, wherein the N-type silicon layer is formed to have an impurity concentration in the range of 1×10¹⁸˜1×10²⁰ ions/cm³.

48. The method according to claim 44, wherein the N-type Is silicon layer is formed by implanting P or As ions with an energy in the range of 10˜100 keV.

49. The method according to claim 44, wherein the P-type silicon layer is formed by implanting B or BF₂ ions with an energy in the range of 10˜100 keV.

50. The method according to claim 44, wherein the P-type silicon layer is formed by implanting B or BF₂ ions with an energy in the range of 10˜100 keV.

51. The method according to claim 26, wherein the method further comprises:
after forming the cell switching elements and before forming the phase change material layer, forming a metal-silicide layer on the cell switching elements.

52. The method according to claim 51, wherein the metal-silicide layer comprises any one of a titanium silicide layer, a niobium silicide layer, and a cobalt silicide layer.

53. The method according to claim 26, wherein the phase change layer is formed of a compound comprising at least one of germanium, stibium, and tellurium.

54. The method according to claim 51, wherein the phase change layer is ion-implanted with at least one of oxygen, nitrogen, and silicon.

55. The method according to claim 26, wherein the top electrodes comprise at least one of TiAlN, TiW, TiN, and WN.

56. The method according to claim 26, wherein the phase change layer and the top electrodes are formed to have a line shape.
